(19) United States
(12) Patent Application Publication
(10) Pub. No.: US 2007/0187843 A1
(43) Pub. Date: Aug. 16, 2007

(54) Semiconductor device having improved wire-bonding reliability and method of manufacturing the same

(76) Inventor: Kwang-jin Kim, Gyeonggi-do (KR)

Correspondence Address: MYERS BIGEL SIBLEY & SAJOVEC, PO BOX 37428, RALEIGH, NC, 27627, US

(21) Appl. No.: 11/704,101

(22) Filed: Feb. 8, 2007

(30) Foreign Application Priority Data
Feb. 10, 2006 (KR) 10-2006-0013130

(51) Int. Cl. H01L 23/48

(52) U.S. Cl. 257/786

(57) ABSTRACT

Semiconductor devices that provide improved wire-bonding reliability are provided. A semiconductor device includes a substrate, an insulating film, a lower protective film, a plurality of bonding pads, and an upper protective film. The insulating film is formed on the substrate and includes a multilayer wiring structure embedded therein. The lower protective film is formed on the insulating film and has a plurality of lower bonding pad openings that are aligned with an uppermost wiring layer of the multilayer wiring structure and are spaced apart from each other in a first direction. The lower protective film has trenches defined therein between adjacent pairs of the lower bonding pad openings. The plurality of bonding pads are in the lower bonding pad openings, are spaced apart from each other in the first direction, and are connected to the uppermost wiring layer of the multilayer wiring structure. An upper protective film fills the trenches in the lower protective film and has a plurality of spaced apart upper bonding pad openings defined therein that expose at least a portion of an upper surface of the bonding pads.

### CROSS REFERENCE TO RELATED APPLICATION

This U.S. non-provisional patent application claims priority under 35 U.S.C § 119 from Korean Patent Application No. 10-2006-0013130 filed on Feb. 10, 2006 in the Korean Intellectual Property Office, the disclosure of which is incorporated herein by reference in its entirety.

### FIELD OF THE INVENTION

The present invention relates to semiconductor devices, and more particularly, to semiconductor devices having improved wire-bonding reliability and methods of manufacturing the same.

### BACKGROUND OF THE INVENTION

Some conventional semiconductor devices include a plurality of bonding pads that connect an internal integrated circuit with external circuitry. The bonding pads can be classified into center-pad type bonding pads, edge-pad type bonding pads and the like, depending upon the positioning of the bonding pads.

As the integration density of semiconductor devices increases, the pitch between bonding pads tends to necessarily decrease. Decreasing the pitch between bonding pads usually also decreases the pitch between the openings that are used to expose the bonding pads for electrical connection with external circuitry.

For example, referring to FIG. 1, a protective layer 10 is formed on a semiconductor substrate. A plurality of spaced apart bonding pads 14 are formed in the protective layer 10. Bonding pad openings 12 are formed in the protective layer 10 and expose the bonding pads 14.

As the pitch between the bonding pad openings 12 decreases, the width of a protective film slit “s” between the bonding pad openings 12 may also decreases. It may also not be possible to reduce the size of each bonding pad opening 12 in proportion to the pitch of the bonding pad openings 12. Therefore, as the pitch of the bonding pad openings 12 is reduced, the width of the slit “s” may be significantly reduced to provide a minimum-bonding margin when the bonding pads are wire-bonded. For example, when the pitch of the bonding pad openings 12 is 60 μm, the width of the slit “s” may be about 24 μm. However, when the pitch of the bonding pad openings 12 is 35 μm, the width of the slit “s” may be significantly reduced to about 8 μm. As a result, some of the slits “s” (indicated as “s”) may be undesirably lifted off (partially removed) during subsequent processes, such as during a back-lapping process or a sawing process, which may cause bonding-faults in subsequent wire-bonding processes.

### SUMMARY OF THE INVENTION

In some embodiments of the present invention, a semiconductor device includes a substrate, an insulating film, a lower protective film, a plurality of bonding pads, and an upper protective film. The insulating film is formed on the substrate and includes a multilayer wiring structure embedded therein. The lower protective film is formed on the insulating film and has a plurality of lower bonding pad openings that are aligned with an uppermost wiring layer of the multilayer wiring structure and are spaced apart from each other in a first direction. The lower protective film has trenches defined therein between adjacent pairs of the lower bonding pad openings. The plurality of bonding pads are in the lower bonding pad openings, are spaced apart from each other in the first direction, and are connected to the uppermost wiring layer of the multilayer wiring structure. An upper protective film fills the trenches in the lower protective film and has a plurality of spaced apart upper bonding pad openings defined therein that expose at least a portion of an upper surface of the bonding pads.

Some other embodiments of the present invention are directed to related methods of manufacturing semiconductor devices. A substrate is provided that has an insulating film in which a multilayer wiring structure is embedded. A lower protective film is formed on the insulating film. The lower protective film has a plurality of lower bonding pad openings that are aligned with an uppermost wiring layer of the multilayer wiring structure and are spaced apart from each other in a first direction. The lower bonding pad openings are filled to form a plurality of bonding pads that are spaced apart from each other in the first direction and are connected to the uppermost wiring layer of the multilayer wiring structure. The trenches in the lower protective film are formed between adjacent pairs of the lower bonding pad openings. An upper protective film is formed that fills the trenches in the lower protective film and has a plurality of spaced apart upper bonding pad openings defined therein that expose at least a portion of an upper surface of the bonding pads.

Further embodiments of the present invention are described below and are shown in the drawings.

### BRIEF DESCRIPTION OF THE DRAWINGS

FIG. 1 is a plan view of a conventional semiconductor device with bonding pad openings in a protective layer, and in which the protective layer that was separating certain adjacent ones of the bonding pad openings has been partially removed (lifted off).

FIG. 2 is a cross-sectional view of a semiconductor device according to some embodiments of the present invention.

FIG. 3 is a partial plan view of the semiconductor device shown in FIG. 2.

FIGS. 4A to 4H are cross-sectional views illustrating methods of manufacturing semiconductor devices according to some embodiments of the present invention.

### DETAILED DESCRIPTION OF EMBODIMENTS OF THE INVENTION

Embodiments of the present invention now will be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like numbers refer to like elements throughout.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present invention. As used herein, the term “and/or” includes any and all combinations of one or more of the associated listed items.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms used herein should be interpreted as having a meaning that is consistent with their meaning in the context of this specification and the relevant art and will not be interpreted in an idealized or overly formal sense unless expressly so defined herein.

It will be understood that when an element such as a film, layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer or region to another element, layer or region as illustrated in the figures. It will be understood that these terms are intended to encompass different orientations of the device in addition to the orientation depicted in the figures.

Embodiments of the invention are described herein with reference to cross-section illustrations that are schematic illustrations of idealized embodiments (and intermediate structures) of the invention. The thickness of films, layers and regions in the drawings may be exaggerated for clarity. Additionally, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. For example, an etched/implanted region illustrated as a rectangle will, typically, have rounded or curved features and/or a gradient of implant concentration at its edges rather than a discrete change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the invention.

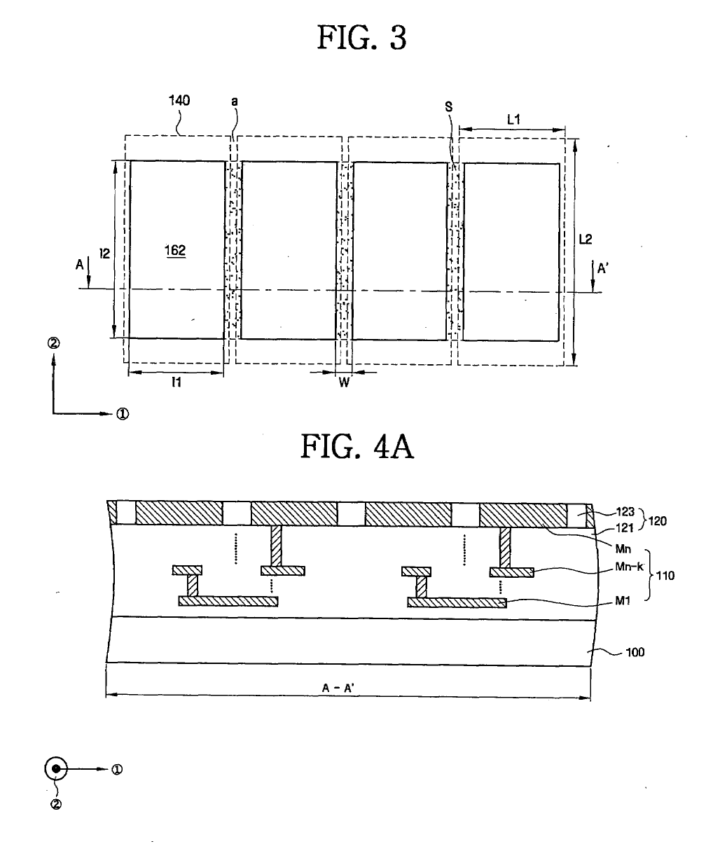

Hereinafter, a semiconductor device according to embodiments of the present invention will be described with reference to FIGS. 2 and 3. FIG. 2 is a cross-sectional view of a semiconductor device according to some embodiments of the present invention, and FIG. 3 is a partial plan view of the semiconductor device. FIG. 2 is a cross-sectional view taken along line A-A′ shown in FIG. 3.

Referring to FIGS. 2 and 3, various semiconductor devices according to some embodiments of the present invention include a substrate 100 and an insulating film 120 on the substrate 100. A multilayer wiring structure 110 is embedded in the insulating film 120. A lower protective film 130 is formed on the insulating film 120. A plurality of bonding pads 140 are connected to an uppermost wiring layer Mn of the multilayer wiring structure 110. An upper protective film 150 is on the lower protective film 130, and has defined therein a plurality of bonding pad openings 162 that expose at least a portion of an upper surface of the bonding pads 140. The substrate 100 may include, but is not limited to, a SOI (Silicon On Insulator) substrate and/or one or more semiconductor materials selected from a group that may consist of Si, Ge, SiGe, GaP, GaAs, SiC, SiGeC, InAs, InP, and/or the like.

An integrated circuit device is formed on the substrate 100. The integrated circuit device includes active elements (not shown), such as transistors, and passive elements (not shown), such as capacitors, resistors, and inductors. The multilayer wiring structure 110 is a wiring structure that is connected to the integrated circuit device to electrically input and output signals to/from the integrated circuit device. The multilayer wiring structure 110 is embedded in the insulating film 120.

In FIG. 2, reference numerals M1 to Mn indicate respective wiring layers of the multilayer wiring structure 110. In particular, reference numeral Mn refers to an uppermost wiring layer of the multilayer wiring structure 110. Here, “n” is an integer number that is larger than “k”. Further, the insulating film 120 may include a plurality of layers, such as one or more interlayer insulating films 121 and thereon a patterned uppermost interlayer insulating film 123. A damascene wiring structure in which an upper surface of the uppermost wiring layer Mn is aligned (flush) with an upper surface of the uppermost interlayer insulating film 123 is exemplified in FIG. 2. Alternatively, the upper surface of the uppermost wiring layer Mn may be aligned with an upper surface of the uppermost interlayer insulating film 123.

The lower protective film 130 is formed on the insulating film 120 and the multilayer wiring structure 110. The lower protective film 130 includes lower bonding pad openings 132 that expose at least a portion of the uppermost wiring layer Mn. The bonding pads 140 are each formed in respective ones of the lower bonding pad openings 132.

The lower protective film 130 is formed on the uppermost wiring layer Mn of the multilayer wiring structure 110 so as to protect the integrated circuit device and the multilayer wiring structure 110, which are on a lower side of the semiconductor device, from environmental conditions such as moisture and/or pressure.

The lower bonding pad openings 132, which expose the uppermost wiring layer Mn, are formed in the lower protective film 130 so as to be spaced apart from each other in a first direction \textcircled{1}. In addition, trenches 134 are formed in the lower protective film 130 between adjacent ones of the lower bonding pad openings 132. An upper protective film 150 is formed on the lower protective film 130 within the trenches 134 and at least a portion of an upper surface of bonding pads 140. The upper protective film 150 is patterned to form slits “S”. The trenches 134 may be formed to perforate through the lower protective film 130 without departing from the scope and spirit of the present invention. The depth t2 of each trench 134, for example, may be in a range of about 0.2 to about 10 μm.

The lower protective film 130, for example, may include a single film such as a silicon oxide film, a silicon nitride film, a silicon oxynitride film, a PSG (phosphor silicate glass) film, or a polyimide film, or may be a laminate of one or more of these films. However, the lower protective film is not limited thereto. A portion of the lower protective film 130 that is not trenched may have a thickness t1 in a range of about 0.2 to about 10 μm.

An etch stopper 129 may be formed between the lower protective film 130 and the uppermost interlayer insulating film 123, such as when forming the lower bonding pad openings 132.

The lower bonding pad openings 132 in the lower protective film 130 are at least partially filled with the bonding pads 140. The bonding pads 140 are configured to be subsequently wire-bonded to an electrical conductor, such as a wire.

In the semiconductor device according to some embodiments of the present invention, the bonding pads 140 are arranged in the first direction \textcircled{1} so as to be spaced apart from each other at a regular pitch, and the lower bonding pad openings 132 are aligned to expose the bonding pads 140. The pitch of the bonding pads 140, for example, may be about 60 μm or less. Each of the bonding pads 140 may be a laminated film formed by laminating barrier films, such as, for example, a titanium film 141 and a titanium nitride film 143, and an aluminum film 145 suitable for wire bonding. However, the bonding pads are not limited thereto.

Each of the bonding pads 140 may have a rectangular shape with a length L2 in the second direction \textcircled{2}, which is larger than a length L1 in the first direction \textcircled{1}. Such a rectangular shape of the bonding pads 140 may allow compensation of the wire-bonding area by elongating the length in the second direction \textcircled{2} in response to a shortening of the length L1 in the first direction due to, for example, a desire to decrease bonding pad pitch and allow higher integration density. However, the bonding pads 140 are not limited to the above pattern, and the shape or length of the bonding pads 140 may be modified without departing from the scope and spirit of the present invention.

The upper protective film 150 has a plurality of upper bonding pad openings 162 defined therein that expose at least a portion of an upper surface of the bonding pads 140. The upper bonding pad openings 162 can be substantially aligned with the bonding pads 140, and, therefore, may have substantially the same pitch as the bonding pads 140. For example, the upper bonding pad openings 162 may be arranged to have a pitch of about 60 μm or less, and a distance W between adjacent ones of the upper bonding pad openings 162 may be about 24 μm or less. It may be found that when the upper bonding pad openings 162 have a pitch of about 35 μm or less therebetween and when a maximum distance W between the upper bonding pad openings 162 is about 8 μm or less, high integration density may be obtained for the semiconductor device.

The upper bonding pad openings 162 are defined by a plurality of slits S of material providing gaps “a” between the bonding pads 140. The bonding pad openings 162 may have a length l2 in the second direction \textcircled{2} that is larger than a length l1 in the first direction \textcircled{1}, which may provide a desirable size wire-bonding area.

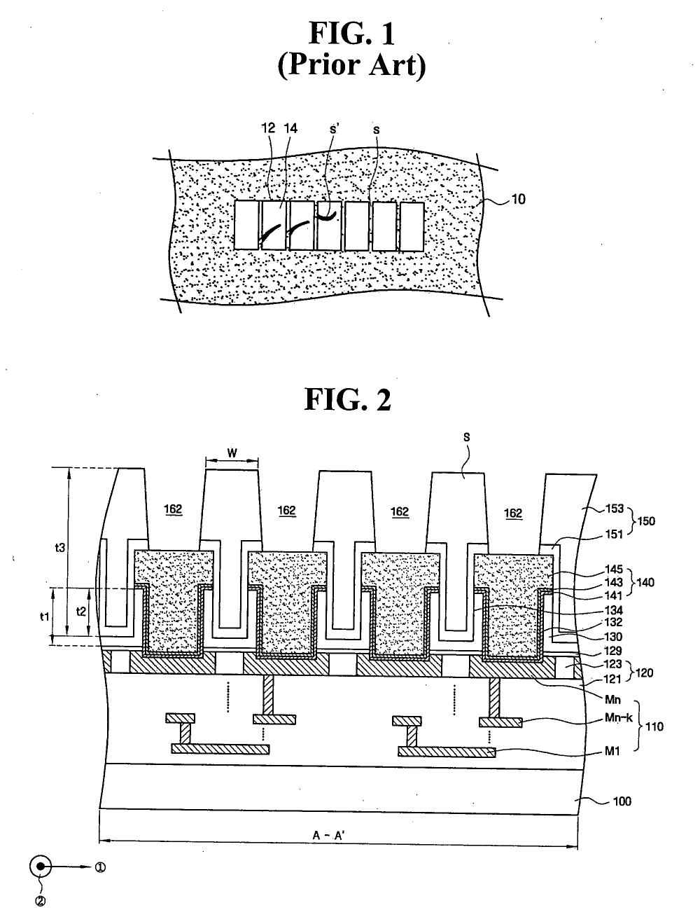

As shown in the drawings, the lower ends of the slits S provided in the upper protective film 150 fill the trenches 134 in the lower protective film 130. As described above, because the lower ends of the slits S of the upper protective film 150 extend into the trenches 134, it is possible to increase a contact area, and thereby an adhesive force, between the slits S and the lower protective film 130. Accordingly, the slits S can be more firmly fixed to the lower protective film than when the lower ends of the slits S are formed on the lower protective film 130. As a result, the lifting phenomenon of the slits S describe with regard to FIG. 1 may be reduced or eliminated in carrying out subsequent processes such as back-lapping processes and/or sawing processes.

The slits S may be formed in the trenches at a height t3 in the range of, for example, about 0.5 to about 30 μm above the bottom surfaces of the trenches 134.

The upper protective film 150 may be a laminated film that includes one or more element protecting liner(s) 151 and a polyimide film 153. The element protecting liner 151 may be formed from, for example, a silicon oxide film, a silicon nitride film, a silicon oxynitride film, and/or a PSG (phosphor silicate glass) film. The polyimide film 153 may be configured to protect elements from various chemicals, alpha particles, radioactive rays, high temperature, and/or friction. The polyimide film 153 may be configured to suppress the growth of cracks caused by differences in thermal expansion coefficients of epoxy compound moldings formed in a succeeding packaging-process and the insulating film 120.

The polyimide film 153 may be made of non-photosensitive polyimide or photosensitive polyimide. In the case of photosensitive polyimide, since fine patterns can be formed without the formation of photoresist patterns, photosensitive polyimide can be effective for forming the polyimide film 153 with highly integrated bonding pad openings 162. The element protecting liner 151 can be configured to improve and complement the protecting effect of the polyimide film 153, but the may also be omitted according to some embodiments.

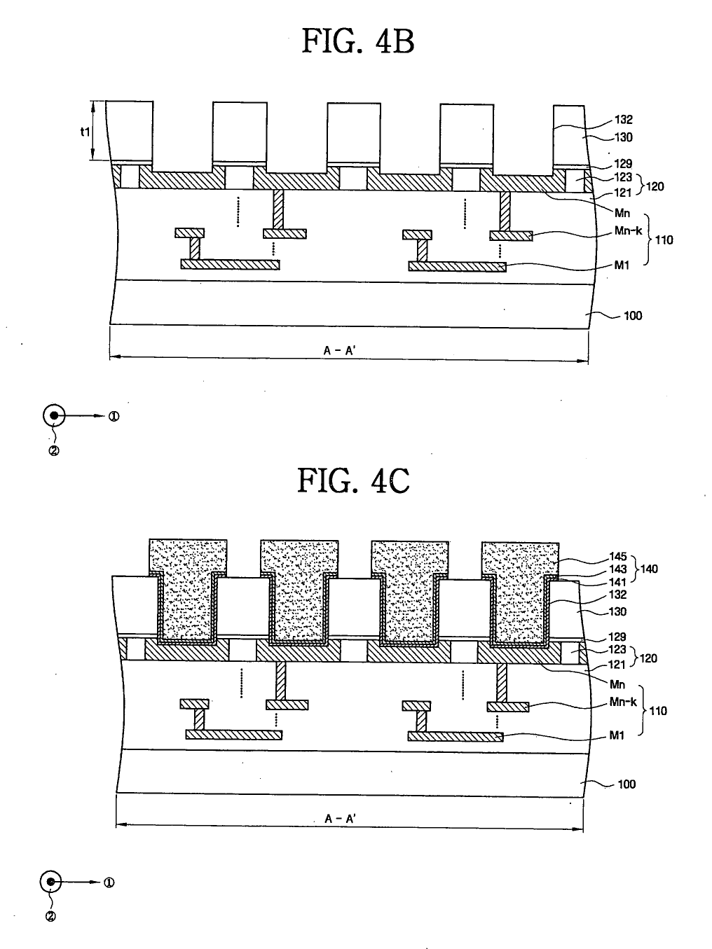

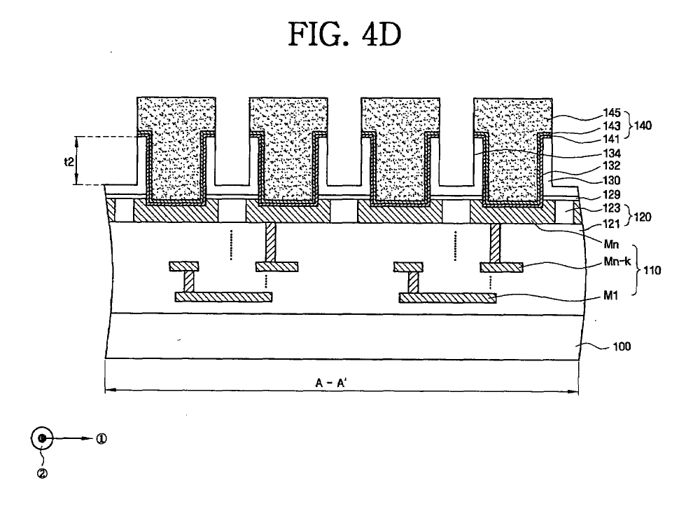

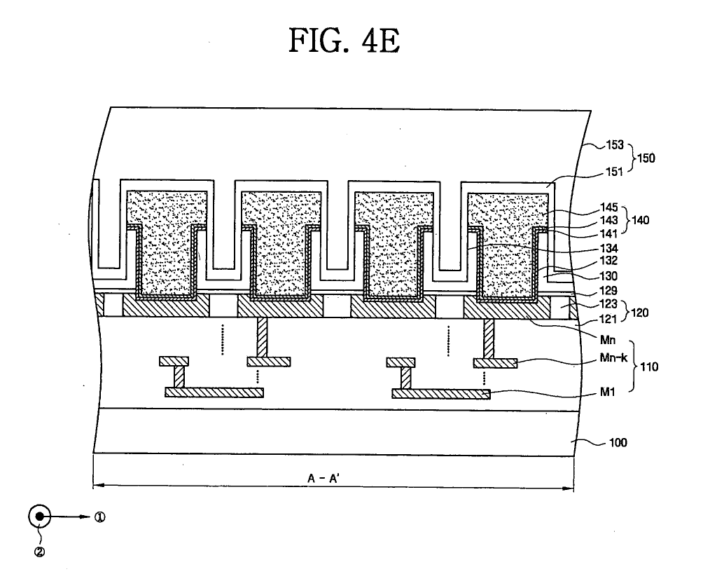

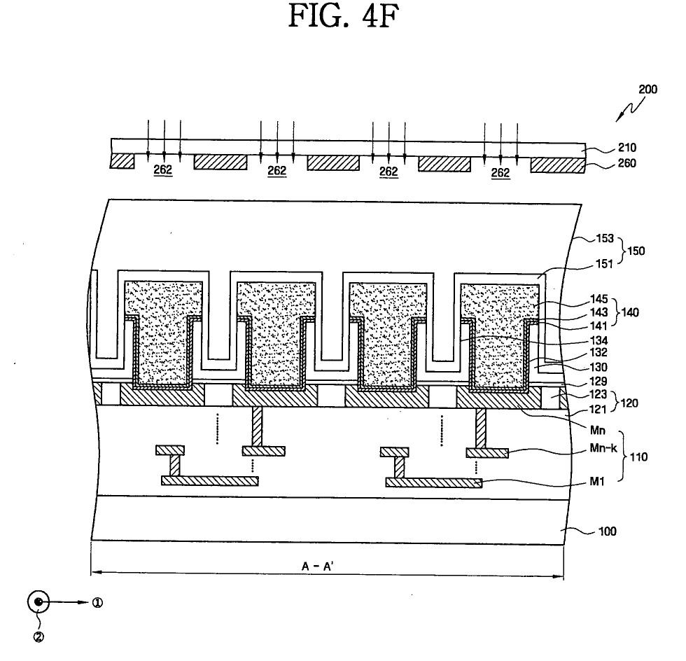

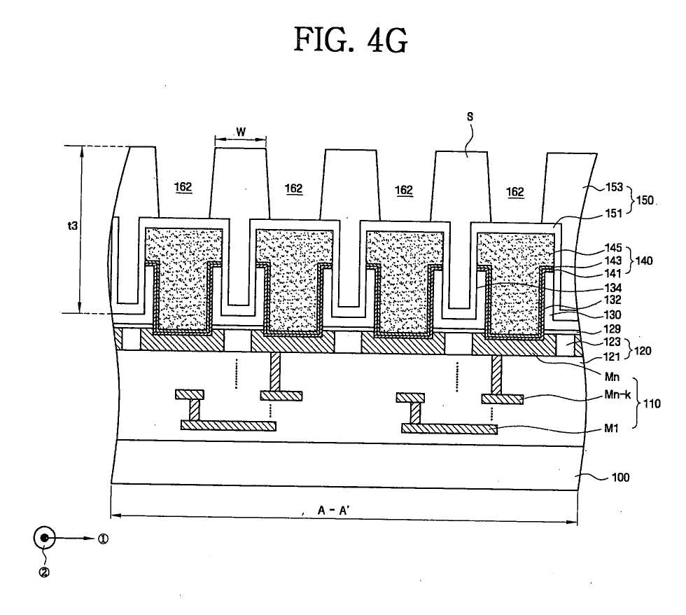

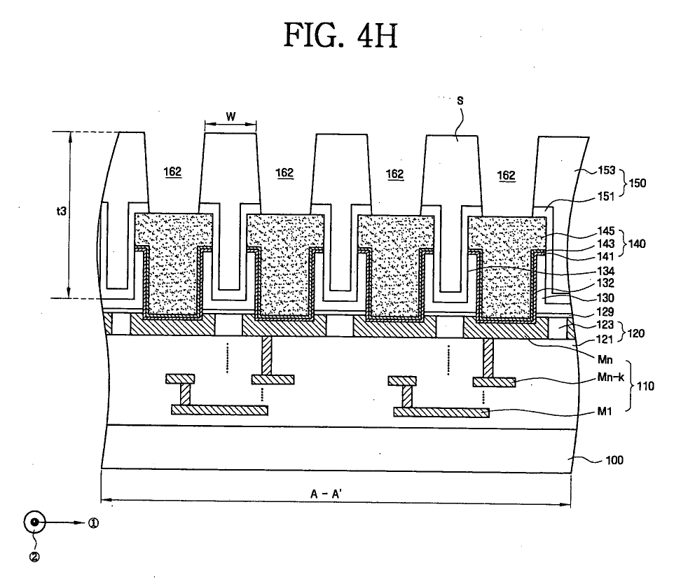

Methods of manufacturing the semiconductor devices, such as the semiconductor devices shown in FIGS. 2 and 3, will be described below with reference to FIGS. 4A to 4H in accordance with some embodiments of the present invention. During the description of the methods of FIGS. 4A to 4H, various semiconductor device components that have the same reference numbers as shown in FIGS. 2 and 3 are to be understood as having the same meaning, and further description thereof will be omitted or only briefly provided to avoid repetition of the description.

As shown in FIG. 4A, the insulating film 120, in which the multilayer wiring structure 110 is embedded, is formed on the semiconductor substrate 100.

As was described above, the semiconductor device includes an integrated circuit device that is formed on the substrate 100. The integrated circuit device includes active elements (not shown) such as transistors, and passive elements (not shown) such as capacitors, resistors, and inductors. The multilayer wiring structure 110 is a wiring structure that is connected to the integrated circuit device to input and output signals to/from the integrated circuit device, and is embedded in the insulating film 120. As was further described above, reference numerals M1 to Mn indicate respective wiring layers of the multilayer wiring structure 110. In particular, reference numeral Mn indicates the uppermost wiring layer of the multilayer wiring structure 110. Here, “n” is an integer larger than “k”.

The lower protective film 130 has lower bonding pad openings 132 defined therein, such as those shown in FIG. 4B.

The etch stopper 129 and the lower protective film 130 are sequentially formed on the insulating film 120 in which the multilayer wiring structure 110 is embedded.

The lower protective film 130 is formed so as to cover the uppermost wiring layer Mn of the multilayer wiring structure 110 and thereby protect the integrated circuit device and the multilayer wiring structure 110, which are formed on the lower side of the semiconductor device, from environmental conditions such as moisture and/or pressure.

The lower protective film 130 may, for example, be a single film such as a silicon oxide film, a silicon nitride film, a silicon oxynitride film, a PSG (phosphor silicate glass) film, or a polyimide film, or may be a laminate of one or more of the those films. The lower protective film 130 may be formed using a CVD, PECVD, PVD, and/or spin coating process. The lower protective film 130 may, for example, be formed to have a thickness t1 in the range of about 0.2 to about 10 μm.

The lower protective film 130 is patterned to form openings that expose the uppermost wiring layer Mn, and the etch stopper 129 exposed through the openings is removed to expose the lower bonding pad openings 132.

As shown in FIG. 4C, diffusion barrier films 141 and 143 and a conductive film 145 made of aluminum may be sequentially formed on the entire surface of the substrate having the bonding pad openings 132. Subsequently, the films 145, 143, and 141 are sequentially patterned to form a plurality of bonding pads 140 that fill the bonding pad openings 132. Each of the diffusion barrier films 141 and 143 prevents the diffusion of the conductive film 145, and may be, for example, a titanium film 141 or a titanium nitride film 143. However, the diffusion barrier films are not limited thereto.

The bonding pads 140 are configured to be wire-bonded, and may be formed so that the plurality of bonding pads 140 are spaced apart from each other in the first direction \textcircled{1} at a regular pitch there between. The bonding pads 140 may be arranged to have a pitch of about 60 μm or less. As described above with reference to FIGS. 2 and 3, each of the bonding pads 140 may have a rectangular pattern that has a length L2 in the second direction \textcircled{2} which is larger than a length L1 in the first direction \textcircled{1}. A sufficiently large wire-bonding area may thereby be obtained.

As shown in FIG. 4D, trenches 134 are formed in the lower protective film 130 between the bonding pads 140. The trenches 134 may be formed during the same patterning process that is used to form the bonding pads 140.

The depth t2 of each trench 134, for example, may be in a range of about 0.2 to about 10 μm, but is not limited thereto. Further, each of the trenches 134 may perforate through the lower protective film 130 so as to expose the etch stopper 129 and/or the insulating layer 120, without departing from the scope and spirit of the present invention.

The upper protective film 150 is formed in the trenches 134 and covers the bonding pads 140, such as that shown in FIG. 4E.

The upper protective film 150 may be a laminated film in which at least one element protecting liner 151 selected from a group consisting of a silicon oxide film, a silicon nitride film, a silicon oxynitride film, and a PSG (phosphor silicate glass) film is laminated with a polyimide film 153. The polyimide film 153 may be formed one or more processes widely known to those skilled in the art of the invention, such as, for example, a spin coating process performed with a spin coater. The thickness of the polyimide film 153 may be reduced in a succeeding curing process relative to the thickness thereof when the polyimide is applied. Accordingly, the thickness of the polyimide film may be selected with consideration of the final thickness thereof.

The polyimide film 153 may be configured to protect elements from various chemicals, alpha particles, radioactive rays, high temperature, and/or friction. In addition, the polyimide film 153 may be configured to suppress the growth of cracks caused by differences in thermal expansion coefficients of the epoxy compound moldings formed in a succeeding packaging-process and the insulating film 120. The element protecting liner 151 may be formed to improve and complement the protecting effect of the polyimide film 153, but may be omitted in some embodiments.

For purposes of illustration and exemplary explanation only, the methods will now be described in the context of the polyimide film 153 being a photosensitive polyimide film.

As shown in FIG. 4F, a photo exposure process is performed on the upper protective film 150 having a positive-photosensitive polyimide film 153. For example, when photosensitive polyimide is used as a least one of the materials of the polyimide film 153, the exposure process may be carried out directly thereon without use of photoresist patterns.

The polyimide film 153 is exposed using a reticle 200 and a light-shielding film 260. The light-shielding film 260 includes polygonal light transmission portions 262 that are spaced apart from each other in the first direction and have the same shapes as the desired bonding pad openings. As a result of the exposure, the exposed portions of the polyimide film 153 are in a condition in which they can be dissolved using a developer.

As shown in FIG. 4G, the exposed polyimide film 153 is patterned using a developer removed the exposed portions.

Subsequently, as shown in FIG. 4H, the patterned polyimide film 153 is used as an etch mask to etch the element protecting liner 151, thereby forming the upper bonding pad openings 162 separated by the slits S. After being cured, the polyimide film 153 can be used as an etch mask. As described above, when the photosensitive polyimide is used as a material of the polyimide film 153, it may be possible to omit a process of forming photoresist patterns and which may simplify the manufacturing process.

As described above, the slits S may be formed to have a height in the range of, for example, about 0.5 to about 30 μm above the bottom surfaces of the trenches 134.

The material of the polyimide film is not limited to the photosensitive polyimide described with regard to FIGS. 4F-H, and may instead be non-photosensitive polyimide. When the polyimide film 153 is a non-photosensitive polyimide film, photoresist patterns may be formed on the polyimide film 153 and such photoresist patterns can be used as an etch mask to sequentially etch the polyimide film 153 and the element protecting liner 151. Accordingly, the upper bonding pad openings 162 may be formed by various different processes. A process of curing the polyimide film 153 may be carried out before the photoresist patterns are formed.

As was described above, because the lower ends of the slits S of the upper protective film 150 extend into the lower protective film 130, the slits S of the upper protective film 150 can be more firmly fixed to the lower protective film and may thereby reduce or prevent the lifting phenomenon or loss thereof that may otherwise occur during subsequent manufacturing processes. As a result, it may be possible to further improve wire-bonding processes and reliability thereof when manufacturing semiconductor devices.

Although the invention has been described in connection with various exemplary embodiments, it will be apparent to those skilled in the art that various modifications and changes may be made thereto without departing from the scope and spirit of the invention. Therefore, it should be understood that the above embodiments are not limitative, but illustrative in all aspects.

What is claimed is:

1. A semiconductor device comprising:
a substrate;
an insulating film formed on the substrate, the insulating film including a multilayer wiring structure embedded therein;
a lower protective film formed on the insulating film, the lower protective film having a plurality of lower bonding pad openings that are aligned with an uppermost wiring layer of the multilayer wiring structure and are spaced apart from each other in a first direction, and the lower protective film having trenches between adjacent pairs of the lower bonding pad openings;
a plurality of bonding pads in the lower bonding pad openings, the bonding pads being arranged to be spaced apart from each other in the first direction and being connected to the uppermost wiring layer of the multilayer wiring structure; and
an upper protective film that fills the trenches in the lower protective film, the upper protective film having a plurality of spaced apart upper bonding pad openings defined therein that expose at least a portion of an upper surface of the bonding pads.

2. The semiconductor device of claim 1, wherein the upper protective film comprises a polyimide film.

3. The semiconductor device of claim 2, wherein the upper protective film comprises a photosensitive polyimide film.

4. The semiconductor device of claim 1, wherein the upper protective film is a laminated film formed by laminating at least one element protecting liner selected from the group consisting of a silicon oxide film, a silicon nitride film, a silicon oxynitride film, a PSG film, and a polyimide film.

5. The semiconductor device of claim 1, wherein a depth of each trench in the lower protective layer is in a range of from about 0.2 to about 10 μm.

6. The semiconductor device of claim 1, wherein the upper bonding pad openings in the upper protective film have a height in a range of from about 0.5 to about 30 μm above bottom surfaces of the trenches in the lower protective film.

7. The semiconductor device of claim 1, wherein the thickness of the lower protective film is in a range of from about 0.2 to about 10 μm.

8. The semiconductor device of claim 1, wherein the plurality of upper bonding pad openings are arranged to be spaced apart from each other with a pitch of about 60 μm or less therebetween.

9. The semiconductor device of claim 8, wherein the distance between the lower bonding pad openings is about 24 μm or less.

10. A method of manufacturing a semiconductor device, the method comprising:
providing a substrate having an insulating film in which a multilayer wiring structure is embedded;
forming a lower protective film on the insulating film, the lower protective film having a plurality of lower bonding pad openings that are aligned with an uppermost wiring layer of the multilayer wiring structure and are spaced apart from each other in a first direction;
filling the lower bonding pad openings to form a plurality of bonding pads that are spaced apart from each other in the first direction and connected to the uppermost wiring layer of the multilayer wiring structure;
forming trenches in the lower protective film between the adjacent pairs of the lower bonding pad openings; and
forming an upper protective film that fills the trenches in the lower protective film and has a plurality of spaced apart upper bonding pad openings defined therein that expose at least a portion of an upper surface of the bonding pads.

11. The method of claim 10, wherein forming an upper protective film comprises forming a polyimide film on the lower protective film.

12. The method of claim 11, wherein forming an upper protective film comprises forming a photosensitive polyimide film on the lower protective film.

13. The method of claim 10, wherein forming an upper protective film comprises:
forming the upper protective film to fill the trenches in the lower protective film and cover the bonding pads; and
patterning the upper protective film to form the plurality of upper bonding pad openings and expose at least a portion of the upper surface of the bonding pads.

14. The method of claim 10, wherein forming an upper protective film comprises:
conformally forming at least one element protecting liner on the lower protective film, wherein the liner is formed from a material selected from the group consisting of a silicon oxide film, a silicon nitride film, a silicon oxynitride film, and a PSG film;
forming a polyimide film on the element protective liner and filling the trenches in the lower protective film; and
sequentially patterning the polyimide film and the element protecting liner to form the plurality of upper bonding pad openings that expose at least a portion of the upper surface of the bonding pads.

15. The method of claim 14, wherein:
the polyimide film is formed from a photosensitive polyimide film; and
the sequentially patterning comprises photo-exposing and developing the photosensitive polyimide film to form photosensitive polyimide patterns, and etching the element protecting liner to form the plurality of upper bonding pad openings using the photosensitive polyimide patterns as an etch mask.

16. The method of claim 10, wherein each of the trenches are formed with a depth in a range of from about 0.2 to about 10 μm in the lower protective film.

17. The method of claim 10, wherein forming an upper protective film comprises forming the upper bonding pad openings to have a height in a range of from about 0.5 to about 30 μm above bottom surfaces of the trenches in the lower protective film.

18. The method of claim 10, wherein the lower protective film is formed with a thickness is in a range of from about 0.2 to about 10 μm.

19. The method of claim 10, wherein forming an upper protective film comprises forming the plurality of bonding pad openings to be spaced apart from each other with a pitch of about 60 μm or less therebetween.

20. The method of claim 10, wherein forming an upper protective layer comprises forming the plurality of bonding pad openings with a distance of 24 μm or less between adjacent bonding pad openings.
